(19) United States
(12) Patent Application Publication
(10) Pub. No.: US 2005/0067690 A1
(43) Pub. Date: Mar. 31, 2005

(54) Highly heat dissipative chip module and its substrate

(76) Inventors: Ming-Hsiang Yang, Taipei (TW); Yuan-Fa Chu, Hsinchu (TW)

Correspondence Address: BIRCH STEWART KOLASCH & BIRCH, PO BOX 747, FALLS CHURCH, VA, 22040-0747, US

(21) Appl. No.: 10/952,863

(22) Filed: Sep. 30, 2004

(30) Foreign Application Priority Data
Sep. 30, 2003 (TW) 92127107

(51) Int. Cl. H01L 23/34

(52) U.S. Cl. 257/706; 257/712; 257/720

(57) ABSTRACT

The specification discloses a highly heat dissipative chip module along with its substrate. The chip module contains a highly heat dissipative substrate with several chips installed thereon. The highly heat dissipative substrate is prepared by forming an insulating layer on the surface of a metal compound plate. A copper wired layer is installed on the insulating layer. The copper wired layer can be used to adhere to the chip. The material of the substrate is preferably an aluminum compound material with a high thermal conduction coefficient. It has the advantages of having a light weight and reducing thermal deformations. The insulating layer is also formed using a material with good thermal conductivity, particularly metal oxides with thermal conduction coefficients higher than resins or fibers. The chip can thus homogeneously distribute heat to the whole printed circuit board, dissipating heat into the ambient space.

### BACKGROUND OF THE INVENTION

1. Field of Invention

The invention relates to a highly heat dissipative chip module and its substrate. In particular, the invention uses an aluminum compound material to form a stacked circuit board with metal compound plates.

2. Related Art

In the trend of having more functions, higher working frequencies, higher speeds, and lighter weights for new electronic devices, the chipset such as the central processing unit (CPU) is also becoming faster, more powerful, and smaller. Consequently, the heat produced by each unit volume becomes higher. The heat dissipation is then a serious problem for electronic devices.

The reason that the performance of an integrated circuit (IC) chip can continuously rise is that the number of transistors that each squared inch can accommodate also increases. As the number of transistors grows, the power consumption also increases. In the past few years, the processes evolve from 32 bit, 66 MHz, 3W to 64 bit, 300 MHz and 10 times the previous power consumption. The power consumption directly generates heat. If the excess heat cannot be released, the lifetime of the chip will be considerably shortened. Whenever the processing temperature is increased by 10 degrees of Celsius, the IC chip lifetime is shortened by a factor of two. To maintain the chip lifetime, one has to use various methods to remove excess heat.

Heat has to propagate via some heat conduction path from the IC chip to the ambient space. The area and heat dissipation of the metal wires on a printed circuit board (PCB) is very limited. One still has to rely on a compound material, such as glass fiber cloths or soft substrates that occupies the largest portion to dissipate heat. However, normal glass fiber cloths or soft substrates do not have good thermal conductivity, the elements of the PCB use air as a thermal conductive medium. Unfortunately, air cooling is not very effective in taking away the heat accumulated on the devices. Eventually, the efficiency of the devices and even the lifetime become lower. This is particularly serious in multi-layered PCB.

### SUMMARY OF THE INVENTION

A first objective of the invention is to provide a highly heat dissipative chip module, which can effectively transfer heat generated from a chip to the substrate surface from whose larger area heat is dissipated into the air.

A second objective of the invention is to provide a material that reduces the thermal dissipation cost of a chip module. The cost of the fan, heat conducting pipes, or heat-dissipating chips required by the chip module can be reduced.

A third objective of the invention is to provide a reliable thermal dissipation means with which one does not need to worry about the breakdown of the chip module or the whole system as a result of the heat dissipation device being out of order.

A fourth objective of the invention is to provide a highly heat dissipative substrate, which uses a highly heat dissipative aluminum compound material to form a metal compound plate. An insulating layer and a circuit layer are directly formed on the surface of the metal compound plate. Using the properties of light weights, high thermal conductivities, and low thermal expansion coefficients, the heat can be directly transferred to the exterior to avoid thermal expansions resulted from a high-temperature environment.

A fifth objective of the invention is to provide a substrate fabrication method, which uses a metal compound plate to form the insulating layer and the circuit layer on its surface. It has a simpler fabrication steps than the multi-layer PCB.

To achieve the above-mentioned objectives, the invention discloses a highly heat dissipative chip module, which contains a highly heat dissipative substrate installed with several chips thereon. The main component of the substrate is a metal compound plate. An insulating layer is formed on the surface of the metal compound plate. The insulating layer is an insulating or polymer film formed with a metal compound. Using surface activation and electroplating processes, a circuit layer is formed on the insulating layer for the purposes of electronic surface adhesion and electrical connections. Since the metal oxides and metal compound plates are materials with good thermal conductivities, the heat generated by the electronic devices on the substrate can be effectively transferred to the whole substrate so that the heat can be dissipate to the air via a larger surface area.

The metal compound plate formed from metal compound materials has a high thermal conduction coefficient as the metals, and the fillings have the properties of high stiffness, low expansion coefficients, and light weights. The applications of the invention in packaging do not only achieve good heat dissipation performance but also have less thermal deformations because of the stiffness of the packaging. The weight of the packaging is much lighter than the prior art.

### BRIEF DESCRIPTION OF THE DRAWINGS

The invention will become more fully understood from the detailed description given hereinbelow illustration only, and thus are not limitative of the present invention, and wherein:

FIG. 1 is a schematic view of the structure of a single-layer substrate in the chip module of the invention;

FIG. 2 is a schematic view of the structure of another single-layer substrate in the chip module of the invention;

FIG. 3 is a schematic view of the structure of a through-hole type double-layer substrate in the chip module of the invention;

FIG. 4 is a schematic view of the structure of another double-layer substrate in the chip module of the invention;

FIG. 5 is the flowchart of the first manufacturing embodiment;

FIG. 6 is the flowchart of the second manufacturing embodiment;

FIG. 7 is the flowchart of the third manufacturing embodiment; and

FIG. 8 is a schematic structural view of the third embodiment.

### DETAILED DESCRIPTION OF THE INVENTION

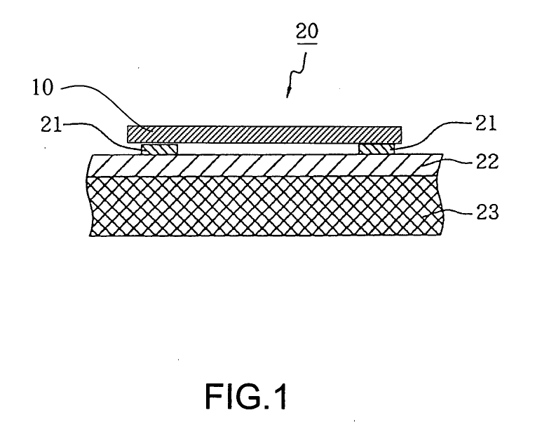

With reference to FIG. 1, an insulating layer 22 covers a metal compound plate 23. The insulating layer is made of a compound of the metal in the metal compound plate, either its oxide or nitride film, or an insulating ceramic material or polymer deposited on the surface of the metal compound plate 23. The insulating film 22 can replace the conventional compound substrate as an electrical insulator between the circuit layer 21 and the metal compound plate 23. For example, take an aluminum-based compound material for the metal compound plate 23 and form an insulator film of aluminum monoxide or aluminum nitride on the surface of the aluminum-based compound material. From Table 1, we see that the thermal conduction coefficient of aluminum is 237 W/M . K, that of aluminum oxide is 46 W/M . K, and that of aluminum nitride is 140 to 230 W/M . K. Generally speaking, the aluminum-based compound material has different thermal conduction coefficients as the fillings change. It is approximately the same as or larger than that of aluminum. The above-mentioned material has a superior thermal conductivity to FR-4 which is 0.2 W/M . K. It also proves that the conventional FR-4 PCB is almost a thermal insulator. On the other hand, both aluminum oxide and aluminum nitride are very good electrical insulators. They can prevent electrons on the circuit layer 21 from penetrating to the metal compound plate 23 to form a short circuit.

TABLE 1

| Material | Thermal conductivity (W/M · K) | Resistance (Ω · cm) |
|---|---|---|
| Aluminum | 237 | 2.8 × 10⁻⁶ |
| Aluminum oxide | 46 | >10¹⁴ |
| Aluminum nitride | 140˜23 | >10¹⁴ |
| FR-4 | 0.2 | >10¹⁴ |

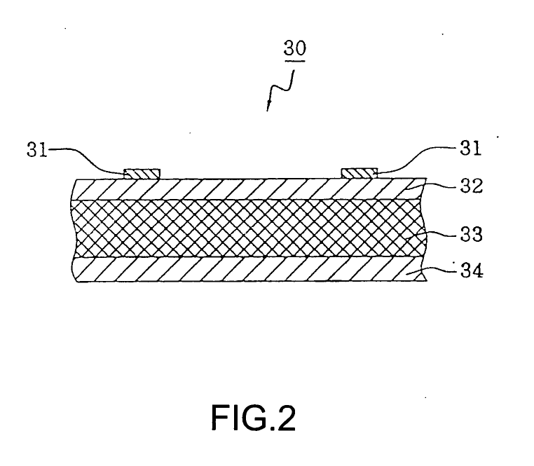

To avoid the exposure of the metal compound plate 33 that will result in touching other circuits in the system and short-circuiting, the bottom of the metal compound plate 33 has to be formed with another insulating layer 34, as shown in FIG. 2. Likewise, the substrate 30 has an insulating layer 32 and a circuit layer 31 stacked in order on the top surface of the metal compound plate 33.

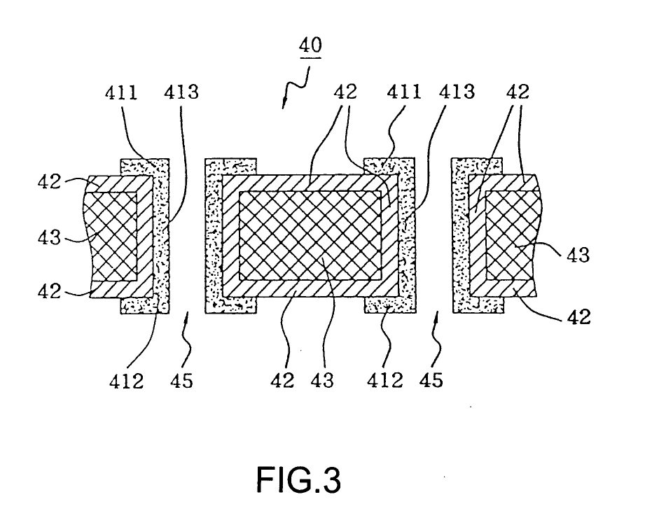

In addition to the substrate suitable for surface mounted devices (SMD), the invention also provides a substrate for socket-type devices. As shown in FIG. 3, the disclosed through-hole type double-layer substrate has a vertical conductive wire 43 on the inner wall of the through hole 45 for electrical communications between the upper and lower circuit layers 411, 412. The interior of the substrate 40 has a metal compound plate 43 that contains several holes. Both the upper and lower surfaces and the holes of the metal compound plate 53 are formed with an insulating layer 42.

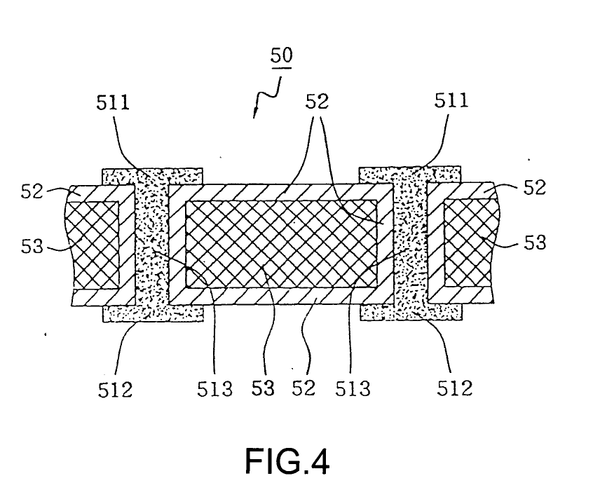

FIG. 4 shows the structure of another double-layer substrate. It is another substrate 50 suitable for SMD. The metal compound plate 53 is also drilled with holes. An insulating layer 52 is formed on the surface around the through holes and of the plate. Vertical wires 513 are provided in the through holes to electrically connect the upper and lower circuit layers 511, 512. This type of substrates 50 can have circuit patterns or SMD installed on both the upper and lower surfaces.

The heat dissipation path is from the interior of the chip to the substrate via the circuit layer(s). A small portion of the heat radiates from the upper surface of the chip. Most of the heat is transferred from the upper insulating layer to the lower insulating layer and then dissipated into the air. The metal compound plate in the middle quickly transfers heat from the upper insulating layer to the lower insulating layer, efficiently distributing the heat on the upper and lower surfaces of the substrate and maximizing the heat dissipating area.

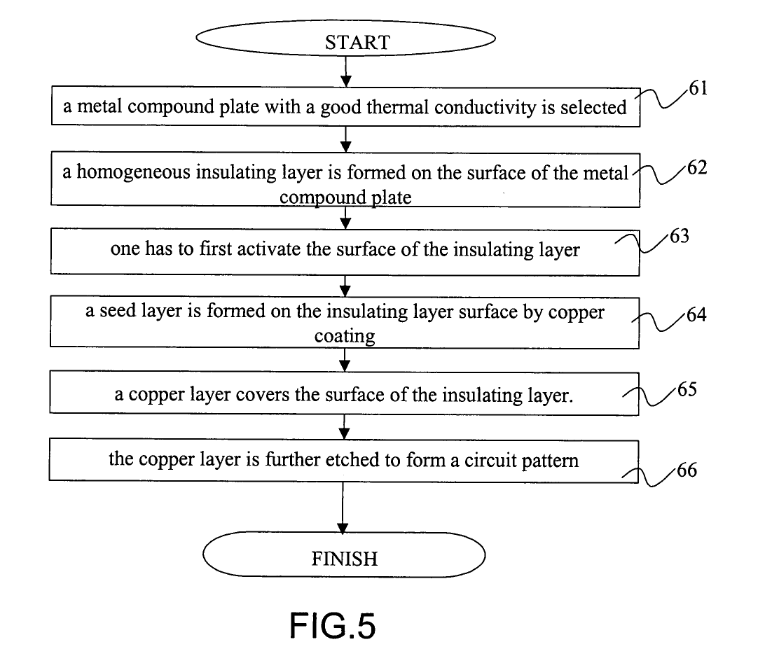

The fabrication method of the above-mentioned substrate can be employed from existing PCB manufacturing method with some improvement, in combination with the advantage of semiconductor processes. FIG. 5 shows the flowchart of a first manufacturing embodiment of the invention. First, a metal compound plate with a good thermal conductivity is selected (step 61). A homogeneous insulating layer is formed on the surface of the metal compound plate (step 62). There are many methods to form the insulating layer, including the thermal oxidation method, vapor deposition, and anode processing. Since the surface of the insulating layer is hard to adhere onto other materials, one has to first activate the surface of the insulating layer (step 63). A seed layer is formed on the insulating layer surface by copper coating (step 64). The seed layer is used for electroplating copper. Therefore, a copper layer covers the surface of the insulating layer (step 65). The copper layer is further etched to form a circuit pattern (step 66) in order to remove the part other than the circuit. The copper coating method in step 64 can be chemical copper coating, physical copper coating, or the conventional embossing method for plastic circuit boards to bond a copper foil with the insulating layer using an adhesive, heat and pressure. In step 65, in addition to chemical copper coating and electroplating to form the copper layer, one may also use the physical copper coating method to form a homogenous copper layer.

The metal compound plate adopts an aluminum-based compound material with good thermal dissipation properties. In particular, the aluminum-based compound materials have the properties of light weights, good erosion resistance, high rigidities, and large strengths in comparison with other metals or alloys. With its unique high thermal conductivities and low thermal expansion coefficients, it is not only able to effectively transfer the heat generated by the electronic device out, but also avoids thermal deformation stress generated due to the rising temperature. The aluminum-based compound materials include silicon-carbonate particle fortified aluminum-based compound materials, carbon fiber fortified aluminum-based compound materials, and diamond particle fortified aluminum-based compound materials.

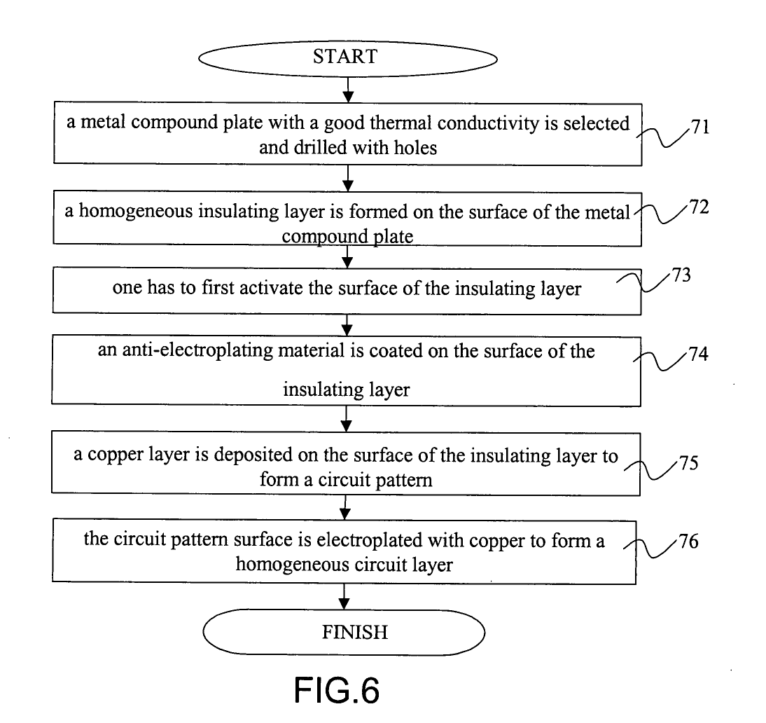

One may also use other methods to form the circuit layer. FIG. 6 shows a second manufacturing embodiment. First, a metal compound plate with a good thermal conductivity is selected and drilled with holes (step 71). A homogeneous insulating layer is formed on the surface of the metal compound plate (step 72). There are many methods to form the insulating layer, including the thermal oxidation method, vapor deposition, and anode processing. Since the surface of the insulating layer is hard to adhere onto other materials, one has to first activate the surface of the insulating layer (step 73). An anti-electroplating material is coated on the surface of the insulating layer (step 74) to cover the part that is not part of the circuit. A copper layer is deposited on the surface of the insulating layer to form a circuit pattern (step 75). Only the part that is not covered with the anti-electroplating material will have chemical copper coating reactions. The circuit pattern surface is electroplated with copper to form a homogeneous circuit layer (step 76). The copper coating method in step 75 can be chemical copper coating, physical copper coating, or thermal embossing. In step 76, in addition to electroplating to form the copper layer, one may also use the chemical copper coating and physical copper coating methods.

The insulating layer can be formed using one method selected from thermal oxidation, vapor deposition, chemical lamination, spraying, coating, soaking, and anode processing. The vapor deposition can be further divided into physical vapor deposition (PVD) and chemical vapor deposition (CVD). Since the copper circuit layer has a bad adhesive property to the insulating layer. One can insert an adhesive layer to increase the combination between the circuit layer and the insulating layer.

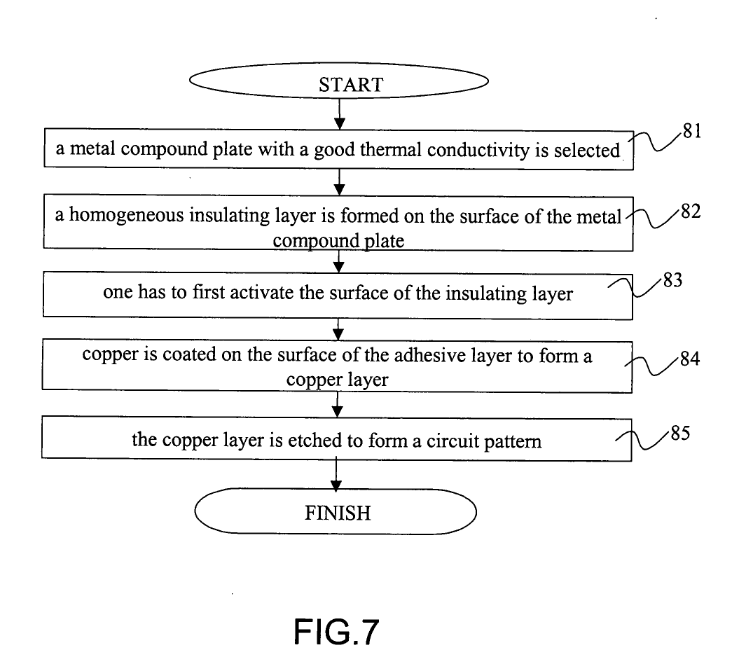

FIG. 7 shows a third manufacturing flowchart of the invention. First, a metal compound plate with a good thermal conductivity is selected (step 81). A homogeneous insulating layer is formed on the surface of the metal compound plate (step 82). There are many methods to form the insulating layer, including the thermal oxidation method, vapor deposition, and anode processing. Since the surface of the insulating layer is hard to adhere onto other materials, one first forms an adhesive layer on the insulating layer (step 83). Copper is coated on the surface of the adhesive layer to form a copper layer (step 84), homogeneously covering the insulating layer surface. The copper layer is etched to form a circuit pattern (step 85), removing the part other than the circuit. In step 84, the method of coating the copper can be chemical coating or physical coating.

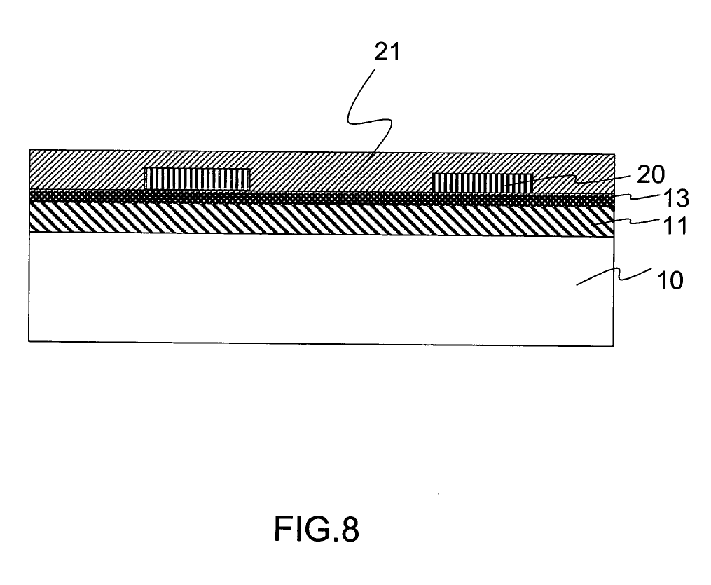

The formation of the adhesive layer is shown in FIG. 8. A copper layer if coated on the surface of the adhesive layer 13 to homogeneously cover the adhesive layer. A circuit pattern 20 is formed by etching the copper layer, removing the part other than the circuit 20. In addition to the steps mentioned above, one can further deposit an oxide insulating layer 21 to evenly cover the circuit 20 for subsequent processes.

The adhesive layer can be made of a material selected from Ti, TiN, WN, TiWN, Ni, Zn, ZnN, Cr, CrN, Ta, and TaN. These materials have good high-temperature stability and conductivity. One may also use an adhesive layer containing Al, Sn, Ni, and their compounds.

Certain variations would be apparent to those skilled in the art, which variations are considered within the spirit and scope of the claimed invention.

1. A highly heat dissipative chip module with a highly heat dissipative substrate and a plurality of chips installed thereon, wherein the substrate comprises:
a metal compound plate, which is formed from an aluminum-based compound material;
an insulating layer, which is formed by covering the surface of the metal compound plate with an insulating material; and
a circuit layer, which is installed on the surface of the insulating layer.

2. The highly heat dissipative chip module of claim 1, wherein an adhesive layer is placed between the insulating layer and the circuit layer for the circuit layer to be attached onto the insulating layer.

3. The highly heat dissipative chip module of claim 2, wherein the adhesive layer is made of a material selected from the group consisting of Ti, TiN, WN, TiWN, Ni, Zn, ZnN, Cr, CrN, Ta, and TaN.

4. The highly heat dissipative chip module of claim 2, wherein the adhesive layer contains a material selected from the group consisting of Al, Sn, Ni, and their compounds.

5. The highly heat dissipative chip module of claim 1, wherein the circuit layer is formed using a method selected form the group consisting of electroplating, chemical copper coating, physical copper coating, and thermal embossing.

6. The highly heat dissipative chip module of claim 1, wherein the aluminum-based compound material is selected from the group consisting of silicon carbonate particle fortified aluminum-based compound materials, carbon fiber fortified aluminum-based compound materials, and diamond particle fortified aluminum-based compound materials.

7. The highly heat dissipative chip module of claim 1, wherein the insulating layer is made of a chemical compound of the metal in the metal compound plate.

8. The highly heat dissipative chip module of claim 1, wherein the insulating layer is made of an oxide.

9. The highly heat dissipative chip module of claim 1, wherein the insulating layer is made of a nitride.

10. The highly heat dissipative chip module of claim 1, wherein the insulating layer is made of a ceramic material.

11. The highly heat dissipative chip module of claim 1, wherein the insulating layer is made of a polymer material.

12. The highly heat dissipative chip module of claim 1, wherein the insulating layer is formed using a method selected from the group consisting of thermal oxidation, vapor deposition, chemical lamination, spraying, coating, soaking, and anode processing.

13. The highly heat dissipative chip module of claim 12, wherein the vapor deposition is the physical vapor deposition (PVD).

14. The highly heat dissipative chip module of claim 12, wherein the vapor deposition is the chemical vapor deposition (CVD).

15. The highly heat dissipative chip module of claim 1, wherein the chip is an electronic device.

16. The highly heat dissipative chip module of claim 15, wherein the electronic device is a surface mounted device (SMD).

17. The highly heat dissipative chip module of claim 1, wherein the metal compound plate has a plurality of through holes with inner walls covered by the insulating layer and a plurality of vertical wires installed on the insulating layer surfaces in the through holes.

18. The highly heat dissipative chip module of claim 17, wherein the chip has a plurality of pins that are plugged into the plurality of through holes and in electrical communications with the circuit layer via the plurality of vertical wires.

19. A highly heat dissipative substrate comprising:
a metal compound plate, which is formed from an aluminum-based compound material;
an insulating layer, which is formed by covering the metal compound plate with an insulating material; and
a circuit layer, which is installed on the surface of the insulating layer.
